(19) United States
(12) Patent Application Publication
(10) Pub. No.: US 2013/0306466 A1
(43) Pub. Date: Nov. 21, 2013

(54) TARGET FOR SPUTTERING AND APPARATUS INCLUDING THE SAME

(71) Applicants: Hong Long NING, Suwon-si (KR); Byeong-Beom KIM, Asan-si (KR); Joon Yong PARK, Gunpo-si (KR); Chang Oh JEONG, Suwon-si (KR); Sang Won SHIN, Yongin-si (KR); Dong Min LEE, Anyang-si (KR); Xun Zhu, Suwon-si (KR)

(72) Inventors: Hong Long NING, Suwon-si (KR); Byeong-Beom KIM, Asan-si (KR); Joon Yong PARK, Gunpo-si (KR); Chang Oh JEONG, Suwon-si (KR); Sang Won SHIN, Yongin-si (KR); Dong Min LEE, Anyang-si (KR); Xun Zhu, Suwon-si (KR)

(73) Assignee: SAMSUNG DISPLAY CO., LTD., Yongin-City (KR)

(21) Appl. No.: 13/617,741

(22) Filed: Sep. 14, 2012

(30) Foreign Application Priority Data
May 18, 2012 (KR) 10-2012-0053110

(51) Int. Cl. C23C 14/08

(52) U.S. Cl. 204/298.13; 204/298.12

(57) ABSTRACT

A sputtering target includes a plurality of targets and edges of the targets overlap each other.

This application claims priority to Korean Patent Application No. 10-2012-0053110 filed on May 18, 2012, and all the benefits accruing therefrom under 35 U.S.C. §119, the entire contents of which are incorporated herein by reference.

### BACKGROUND

(a) Field

The invention relates to a target for sputtering and an apparatus including the target, and more particularly, to a target for sputtering that can reduce or effectively prevent contamination of a pattern in sputtering, and a target apparatus for sputtering including the target for sputtering.

(b) Description of the Related Art

Sputtering may be used to form a thin metal layer in the process of manufacturing a semiconductor device, a liquid crystal display, an organic light emitting device, etc.

Sputtering is a kind of vacuum deposition and is a method of forming a layer on a substrate, by generating plasma under a relatively low level of vacuum and accelerating gas such as ionized argon, and applying the plasma onto a target such that desired atoms are discharged from the target.

As the size of display devices increases, sputtering apparatuses have correspondingly increased in size. Large-sized production equipment is necessary for manufacturing the large-sized sputtering apparatuses, and accordingly, the cost increases.

### SUMMARY

One or more exemplary embodiment of the invention provides a target for sputtering, and a target apparatus for sputtering including the target for sputtering, having advantages of reducing or effectively preventing contamination of a pattern during sputtering.

An exemplary embodiment of the invention provides a sputtering target that includes a plurality of targets, in which the edges of the plurality of targets overlap each other.

A first target of the plurality of targets may include a first main target, and a first protrusion protruding from a side surface of the first main target.

A second target of the plurality of targets may include a second main target, and a second protrusion protruding from a side surface of the second main target.

The first protrusion of the first target and the second protrusion of the second target may overlap each other.

The first protrusion may protrude from an upper thickness portion of the side surface of the first main target, and the second protrusion may protrude from a lower thickness portion of the side surface of the second main target.

The first target including the first protrusion may further include a first space positioned under the first protrusion, and the second protrusion may be in the first space.

The second target including the second protrusion may further include a second space positioned under the second protrusion, and the first protrusion may be in the second space.

A third target of the plurality of targets may include a third main target, a first protrusion and a second protrusion, and the first protrusion and the second protrusion of the third target may protrude from opposing side surfaces of the third main target.

The first target including the first protrusion may further include a third protrusion protruding from the side surface of the first main target, at a predetermined distance from the first protrusion.

The first, second and third protrusions may overlap each other.

The first protrusion may protrude from an upper thickness portion of the side surface of the first main target, the second protrusion may protrude from a middle thickness portion of the side surface of the second main target, and the third protrusion may protrude from a lower thickness portion of the side surface of the first main target.

The target including the first protrusion and the third protrusion may further include a first space positioned between the first protrusion and the third protrusion, and the second protrusion may be in the first space.

The target including the second protrusion may further include a second space positioned above the second protrusion and a third space positioned under the second protrusion, the first protrusion may be in the second space, and the third protrusion may be in the second space.

The plurality of targets may include at least one of indium zinc oxide (“IZO”), indium tin oxide (“ITO”), gallium indium zinc oxide (“GIZO”), tin indium zinc oxide (“TIZO”), indium zinc tin oxide (“InZTO”) and amorphous indium gallium zinc oxide (“a-IGZO”).

Another exemplary embodiment of the invention provides a target apparatus for sputtering, including: a backing plate; a sputtering target which includes a plurality of targets on the backing plate; and an adhesive member between the backing plate and the target for sputtering, the adhesive member fixing the sputtering target to the backing plate, in which edges of the plurality of targets overlap each other.

The adhesive member may include indium.

A first target of the plurality of targets may include a first main target, and a first protrusion protruding from an upper thickness portion of a side surface of the first main target.

A second target of the plurality of targets may include a second main target, and a second protrusion protruding from a lower thickness portion of a side surface of the second main target.

The first and second protrusions overlap each other.

Yet another exemplary embodiment of the invention provides a target apparatus for sputtering, including: a cylindrical backing body; a sputtering target including a plurality of targets which surround an outer side surface of the cylindrical backing body; and an adhesive member between the cylindrical backing body and the sputtering target, the adhesive member fixing the sputtering target to the cylindrical backing body, in which the edges of the plurality of targets overlap each other.

One or more exemplary embodiment of the sputtering target according to the invention and a target apparatus for sputtering that includes the sputtering target have the following effects.

The sputtering target according to the invention and a target apparatus for sputtering that includes the sputtering target have an effect of reducing or effectively preventing contamination of a pattern during sputtering by preventing exposure of the adhesive through the spaces between a plurality of targets of the sputtering target.

Further, no specific arrangement part is required to fit and arrange the protrusions and the spaces, by inserting the protrusion of any one target into the space of an adjacent target.

In addition, as contamination of the pattern is reduced or effectively prevented during sputtering, it is possible to improve uniformity of the pattern and increase the life span of the sputtering target.

### BRIEF DESCRIPTION OF THE DRAWINGS

The above and other features of this disclosure will become more apparent by describing in further detail exemplary embodiments thereof with reference to the accompanying drawings, in which:

FIG. 1 is a top plan view of an exemplary embodiment of a target apparatus for sputtering according to the invention.

FIG. 2 is a cross-sectional view of the target apparatus for sputtering according to the invention, taken along line II-II of FIG. 1.

FIG. 3 is a perspective view showing an exemplary embodiment of a first target of the target apparatus for sputtering according to the invention.

FIG. 4 is a perspective view showing an exemplary embodiment of a second target of the target apparatus for sputtering according to the invention.

FIG. 5 is a perspective view showing an exemplary embodiment of a third target of the target apparatus for sputtering according to the invention.

FIG. 6 is a cross-sectional view showing an exemplary embodiment of a sputtering apparatus including the target apparatus for sputtering according to the invention.

FIG. 7 is a cross-sectional view of another exemplary embodiment of a target apparatus for sputtering according to the invention.

FIG. 8 is a perspective view showing another exemplary embodiment of a first target of the target apparatus for sputtering according to the invention.

FIG. 9 is a perspective view showing another exemplary embodiment a second target of the target apparatus for sputtering according to the invention.

FIG. 10 is a perspective view showing another exemplary embodiment of a third target of the target apparatus for sputtering according to the invention.

FIG. 11 is a perspective view of another exemplary embodiment of a target apparatus for sputtering according to the invention.

FIG. 12 is a cross-sectional view of the target apparatus for sputtering according to the invention, taken along line XII-XII of FIG. 11.

FIG. 13 is a cross-sectional view of the target apparatus for sputtering according to the invention, taken along line XIII-XIII of FIG. 11.

### DETAILED DESCRIPTION

The invention will be described hereinafter more fully hereinafter with reference to the accompanying drawings, in which exemplary embodiments of the invention are shown. As those skilled in the art would realize, the described embodiments may be modified in various different ways, all without departing from the spirit or scope of the invention.

In the drawings, the thickness and spaces of layers, films, panels, regions, etc., are exaggerated for clarity. Like reference numerals designate like elements throughout the specification. As used herein, the term “and/or” includes any and all combinations of one or more of the associated listed items. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “under” or “lower” relative to other elements or features would then be oriented “above” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A target for sputtering is fixed to a backing plate, with a predetermined thickness. In the related art, even though one target for sputtering is fixed to a backing plate, a method of fixing a plurality of targets for sputtering to a backing plate and of using the plurality of targets in order to reduce costs has been proposed, in consideration of the size increases in sputtering apparatuses, production equipment, display devices, etc.

An adhesive is provided between the target for sputtering and the backing plate to fix the target for sputtering to the backing plate. Where a plurality of targets for sputtering is employed, there are spaces between the targets for sputtering and the adhesive may be exposed through the spaces.

Due to the spaces between the targets for sputtering, plasma and/or the adhesive exposed to high temperature may protrude outward from the spaces during sputtering. The components of the protruded adhesive undesirably contaminate a pattern formed on the substrate.

Hereinafter, the invention will be described in detail with reference to the accompanying drawings.

Exemplary embodiments of a target apparatus for sputtering according to the invention will be described with reference to the accompanying drawings.

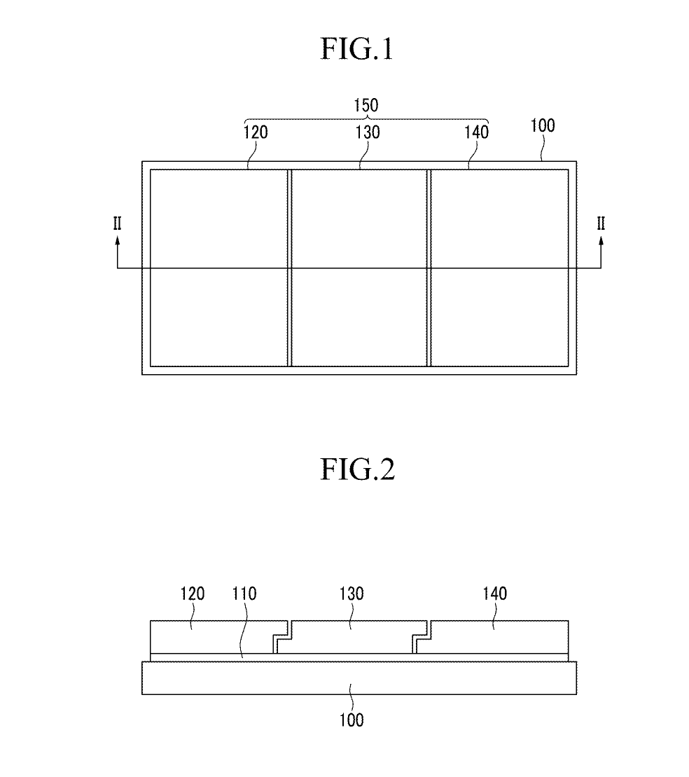

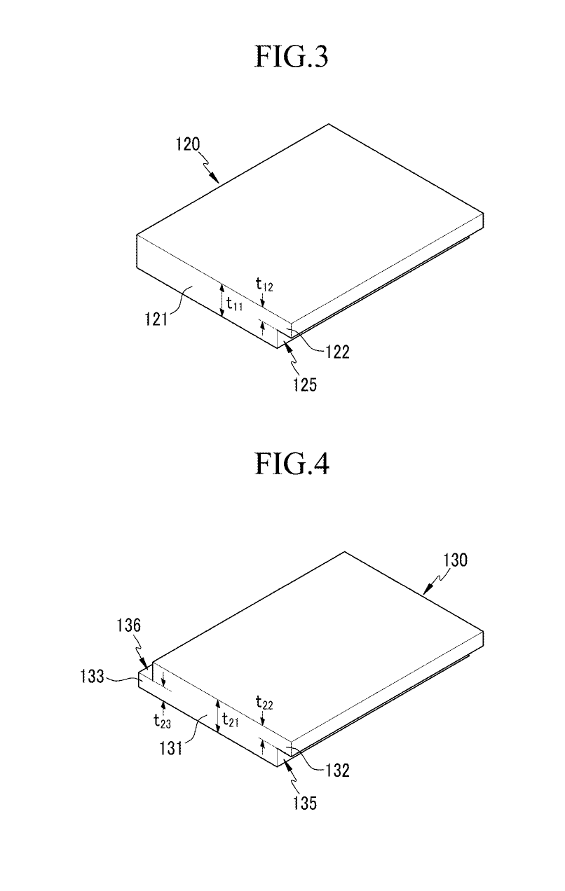

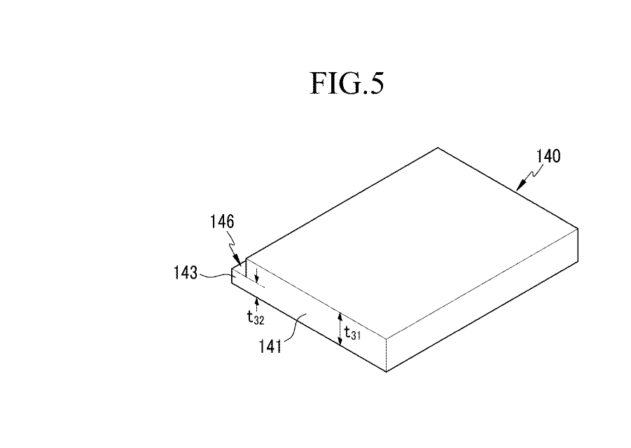

FIG. 1 is a top plan view of an exemplary embodiment of a target apparatus for sputtering according to the invention and FIG. 2 is a cross-sectional view of the target apparatus for sputtering according to the invention, taken along line II-II of FIG. 1. FIG. 3 is a perspective view showing an exemplary embodiment of a first target of the target apparatus for sputtering according to the invention, FIG. 4 is a perspective view showing an exemplary embodiment of a second target of the target apparatus for sputtering according to the invention, and FIG. 5 is a perspective view showing an exemplary embodiment of a third target of the target apparatus for sputtering according to the invention.

An exemplary embodiment of a target apparatus for sputtering according to the invention, as shown in FIGS. 1 and 2, includes a backing plate 100, and a target 150 for sputtering on the backing plate 100.

The backing plate 100 supports the target 150 for sputtering. The backing plate 100 may include copper, titanium or stainless steel, which have high electric conductivity and thermal conductivity, but is not limited thereto or thereby.

An adhesive member 110 may be further provided between the target 150 for sputtering and the backing plate 100 to fix the target 150 for sputtering to the backing plate 100. The adhesive member 110 may include indium or an indium-tin alloy, but is not limited thereto or thereby. The indium has a melting point, not relatively high, at about 158.6 degrees Celsius (° C.), such that the indium is a substance that allows a decrease in the temperature of a process of bonding the target 150 for sputtering to the backing plate 100, and is easily handled.

The target 150 for sputtering includes a first target 120, a second target 130 and a third target 140. Although the target 150 for sputtering is composed of three targets 120, 130 and 140 in the drawings, the invention is not limited thereto. The number of targets may be appropriately selected in consideration of the size of the backing plate, the sizes of a plurality of targets and the size of the substrate which will include a pattern thereon.

Edges of the first, second and third targets 120, 130 and 140 overlap each other. The first target 120, the second target 130 and the third target 140 are sequentially arranged from the left edge of the target 150 for sputtering. The right edge of the first target 120 and the left edge of the second target 130 overlap each other while the right edge of the second target 130 and the left edge of the third target 140 overlap each other.

The material of the target 150 for sputtering may be selected and used in accordance with the metal for forming the pattern. In one exemplary embodiment, for example, the material of the target 150 for sputtering may include at least one of indium zinc oxide (“IZO”), indium tin oxide (“ITO”), gallium indium zinc oxide (“GIZO”), tin indium zinc oxide (“TIZO”), indium zinc tin oxide (“InZTO”), and amorphous indium gallium zinc oxide (“a-IGZO”).

The shapes of the targets 120, 130 and 140 are described hereafter.

Referring to FIG. 3, the first target 120 includes a main target 121, a first protrusion 122 that protrudes from one side surface of the main target 121, and a first space 125 positioned under the first protrusion 122.

The main target 121 is substantially a rectangular parallelepiped shape. In one exemplary embodiment, for example, the main target 121 may be plate-shaped having a flat top and/or bottom, and a predetermined thickness.

The thickness of the plate-shaped main target 121 may be substantially uniform, but is not limited thereto or thereby.

The first protrusion 122 protrudes from an upper portion or half of the one side surface of the main target 121. Material of the first target 120 may not be protruded from a lower portion or half of the one side surface of the main target 121. An upper surface of the first protrusion 122 is coplanar with an upper surface of the main target 121. The main target 121 includes four side surfaces which connect the upper surface and a lower surface thereof.

In one exemplary embodiment, the first protrusion 122 may protrude from a right side surface of the main target 121. The first protrusion 122 may protrude from the entire upper half of the main target 121, when the right side surface of the main target 121 is divided into an upper half and a lower half which have the same area. When the first protrusion 122 protrudes from the entire upper half of the main target 121, end surfaces of the first protrusion 122 may be coplanar with side surfaces of the main target 121 adjacent to the right side surface.

The first space 125 of the first target 120 is adjacent to the right side surface of the main target 121 and under the first protrusion 122. The first protrusion 122 exposes the lower half of the right side surface. The space positioned at the right side surface of the lower half of the main target 121, and excluding the first protrusion 122 which protrudes from the right side surface of the main target 121, is the first space 125.

A lower surface of the first protrusion 122 is non-coplanar with a lower surface of the main target 121. A distance between the lower surfaces of the first protrusion 122 and the main target 121 may define a stepped portion corresponding to the space 125.

Referring to FIG. 4, the second target 130 includes a main target 131, a first protrusion 132 that protrudes from one side surface of the main target 131, and a first space 135 positioned under the first protrusion 132. Further, the second target 130 includes a second protrusion 133 protruding from a side surface of the main target 131 opposing the one side surface, and a second space 136 positioned above the second protrusion 133.

The shape of the main target 131 of the second target 130 is similar to the shape of the main target 121 of the first target 120.

The shapes of the first protrusion 132 and the first space 135 of the second target 130 are also similar to the shapes of the first protrusion 122 and the first space 125 of the first target 120.

The first protrusion 132 protrudes from an upper half of the right side surface of the main target 131. The first space 135 of the second target 130 is adjacent to the right side surface of the main target 131 and under the first protrusion 132.

The second protrusion 133 protrudes from the lower half of the left side surface of the main target 131 opposite to the right side surface. The second protrusion 133 may protrude from the entire lower half of the main target 131, when the left side surface of the main target 131 is divided into an upper half and a lower half which have the same area. When the second protrusion 133 protrudes from the entire lower half of the main target 131, end surfaces of the second protrusion 133 may be coplanar with side surfaces of the main target 131 adjacent to the left side surface.

The second space 136 of the second target 130 is adjacent to the left side surface of the main target 131 and above the second protrusion 133. The second protrusion 133 exposes the upper half of the left side surface. The space positioned at the left side surface of the upper half of the main target 131, and excluding the second protrusion 133 with protrudes from the left side surface of the main target 131, is the second space 136.

A lower surface of the second protrusion 133 is coplanar with a lower surface of the main target 131. An upper surface of the second protrusion 133 is non-coplanar with an upper surface of the main target 131. A distance between the upper surfaces of the second protrusion 133 and the main target 131 may define a stepped portion corresponding to the space 136.

Referring to FIG. 5, the third target 140 includes a main target 141, a second protrusion 143 that protrudes from one side surface of the main target 141, and a second space 146 positioned above the second protrusion 143.

The shape of the main target 141 of the third target 140 is similar to the shape of the main target 131 of the second target 130.

The shapes of the second protrusion 143 and the second space 146 of the third target 140 are also similar to the shapes of the second protrusion 133 and the second space 136 of the second target 130.

The second protrusion 143 protrudes from the lower half of the left side surface of the main target 141. The second space 146 of the third target 141 is adjacent to the left side of the main target 141 and above the second protrusion 143.

The combination relationship of the first target 120, the second target 130 and the third target 140 is described with reference to FIGS. 2 to 5.

As the right edge of the first target 120 and the left edge of the second target 130 overlap each other, the first target 120 and the second target 130 are combined. In this state, the first protrusion 122 of the first target 120 overlaps the second protrusion 133 of the second target 130. The first protrusion 122 of the first target 120 is inserted in the second space 136 of the second target 130. The second protrusion 133 of the second target 130 is inserted in the first space 125 of the first target 120.

An overall thickness of the target 150 for sputtering may be substantially constant and uniform before and after the first target 120 and the second target 130 are combined. The top of the target 150 for sputtering is made flat when the first and second targets 120 and 130 are coupled.

For this configuration, the sum of the thickness t₁₂ of the first protrusion 122 of the first target 120 and the thickness t₂₃ of the second protrusion 133 of the second target 130 may be substantially the same as the thickness t₁₁ of the main target 121 of the first target 120 or the thickness t₂₁ of the main target 131 of the second target 130.

The thickness t₁₁ of the main target 121 of the first target 120 is substantially the same as the thickness t₂₁ of the main target 131 of the second target 130.

The thickness t₁₂ of the first protrusion 122 of the first target 120 may be substantially half the thickness t₁₁ of the main target 121 of the first target 120. The thickness t₂₃ of the second protrusion 133 of the second target 130 may be substantially half the thickness t₂₁ of the main target 131 of the second target 130.

The second target 130 and the third target 140 are combined by overlapping the right edge of the second target 130 and the left edge of the third target 140. In this state, the first protrusion 132 of the second target 130 overlaps the second protrusion 143 of the third target 140. The first protrusion 132 of the second target 130 is inserted in the second space 146 of the third target 140. The second protrusion 143 of the third target 140 is inserted in the first space 135 of the second target 130.

An overall thickness of the target 150 for sputtering may be substantially constant and uniform before and after the second target 130 and the third target 140 are combined. The top of the target 150 for sputtering is made flat when the second and third targets 130 and 140 are coupled.

For this configuration, the sum of the thickness t₂₂ of the first protrusion 132 of the second target 130 and the thickness t₃₂ of the second protrusion 143 of the third target 140 may be substantially the same as the thickness t₂₁ of the main target 131 of the second target 130 or the thickness t₃₁ of the main target 141 of the third target 140.

The thickness t₂₁ of the main target 131 of the second target 130 is substantially the same as the thickness t₃₁ of the main target 141 of the third target 140.

The thickness t₂₂ of the first protrusion 132 of the second target 130 may be substantially half the thickness t₂₁ of the main target 131 of the second target 130. The thickness t₃₂ of the second protrusion 143 of the third target 140 may be substantially half the thickness t₃₁ of the main target 141 of the third target 140.

The first, second and third targets 120, 130 and 140 may be spaced apart from each other in the left-right direction. However, owing to the protrusions of one target inserted into a space of an adjacent target, a path from the adhesive member 110 to an outside of the targets is non-linear in a direction perpendicular to an upper surface of the adhesive 110.

In the exemplary embodiment of the invention shown in FIG. 1 to FIG. 5, the first target 120 includes the first protrusion 122, the third target 140 includes the second protrusion 143, and the second target 130 includes the first protrusion 132 and the second protrusion 133. Therefore, the first target 120 and the third target 140 are coupled to opposing sides of the second target 130.

In an alternative exemplary embodiment, in order to implement a target 150 for sputtering composed of four targets by modifying the exemplary embodiment of the invention shown in FIG. 1 to FIG. 5, one target with a first protrusion, one target with a second protrusion, and two targets with both a first protrusion and a second protrusion may be used.

Further, the shapes of a plurality of targets constituting a collective target 150 for sputtering may be freely changed and it is possible to overlap two adjacent targets through various modifications. The plurality of targets having complementing protrusions and spaces are individually separable from each other and assemblable to each other, to form the collective target 150 for sputtering.

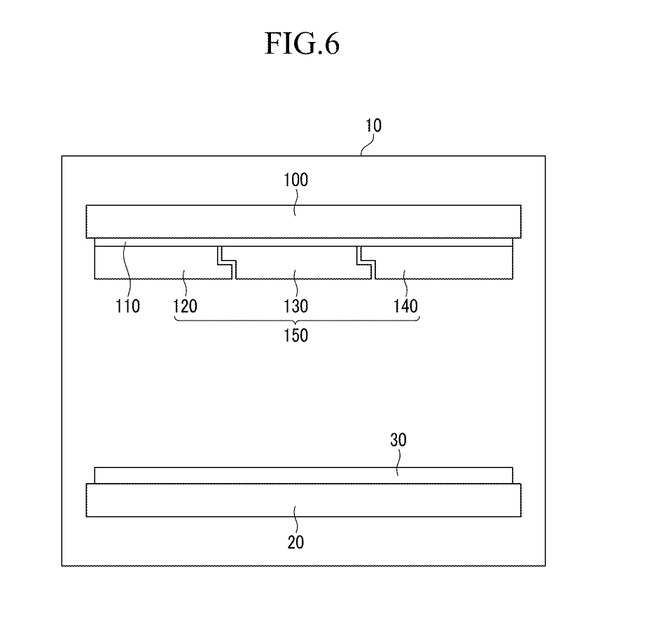

Next, an exemplary embodiment of a sputtering apparatus including the target apparatus for sputtering according to the invention is described with reference to FIG. 6.

FIG. 6 is a cross-sectional view showing an exemplary embodiment of a sputtering apparatus including the target apparatus for sputtering according to the invention.

An exemplary embodiment of a sputtering apparatus including the target apparatus for sputtering according to the f invention includes a chamber 10 that maintains a vacuum, a susceptor 20 positioned under the chamber 10, and a backing plate 100 positioned at an upper portion in the chamber 10.

A substrate 30 which will include a pattern thereon is placed on the susceptor 20, and a target 150 for sputtering is positioned on the back plate 100.

A direct current (“DC”) voltage is applied to the susceptor 20 and the backing plate 100, and a gas such as argon is injected to the chamber 10 in order to perform sputtering. Plasma is produced between the susceptor 20 and the backing plate 100 and the ions of the argon gas hit the target 150 for sputtering. Atoms are discharged from the target 150 for sputtering and adhere onto the substrate 30, such that a thin metal layer is deposited on the substrate 30. In this process, the susceptor 20 may function as an anode and the backing plate 100 may function as a cathode, but is not limited thereto or thereby.

Since fine spaces are defined at the joint between the first target 120 and the second target 130 and at the joint between the second target 130 and the third target 140, in the target 150 for sputtering, the argon gas may flow inside the target 150 for sputtering through the fine spaces and influence sputtering during the sputtering process.

However, since the edge of the first target 120 and the edge of the second target 130 overlap each other, the ions of the argon gas from outside the target 150 for sputtering hit the second target 130 even though flowing into the fine space between the first target 120 and the second target 130, such that the ions do not reach the adhesive member 110. Further, since the edge of the second target 130 and the edge of the third target 140 overlap each other, the ions of the argon gas hit the third target 140 even though flowing into the fine space between the second target 130 and the third target 140, such that the ions cannot reach the adhesive member 110.

Therefore, even though the adhesive member 110 is exposed to the outside via the fine spaces between the targets, leakage of the components of the adhesive member 110 is reduced or effectively prevented, and contamination of the pattern formed on the substrate 30 is reduced or effectively prevented.

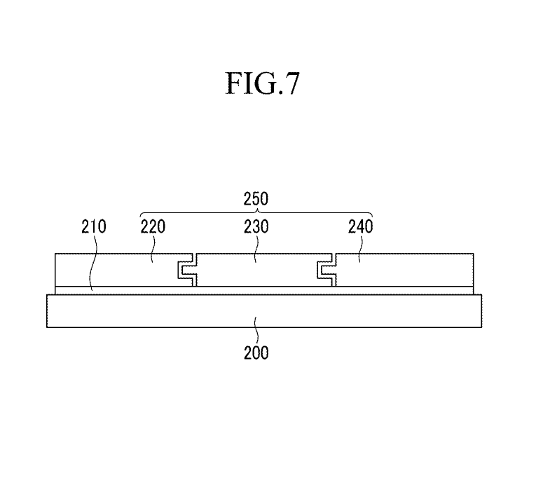

Next, another exemplary embodiment of a target apparatus for sputtering according to the invention is described with reference to FIGS. 7 to 10.

Since the target apparatus for sputtering according to the invention in FIGS. 7 to 10 is substantially the same as that of the exemplary embodiment in FIGS. 1 to 5, the same parts are not described and only the parts with differences are described hereafter. The most remarkable difference from the exemplary embodiment in FIGS. 1 to 5 is the shapes of the edge of the targets, which is described in detail hereafter.

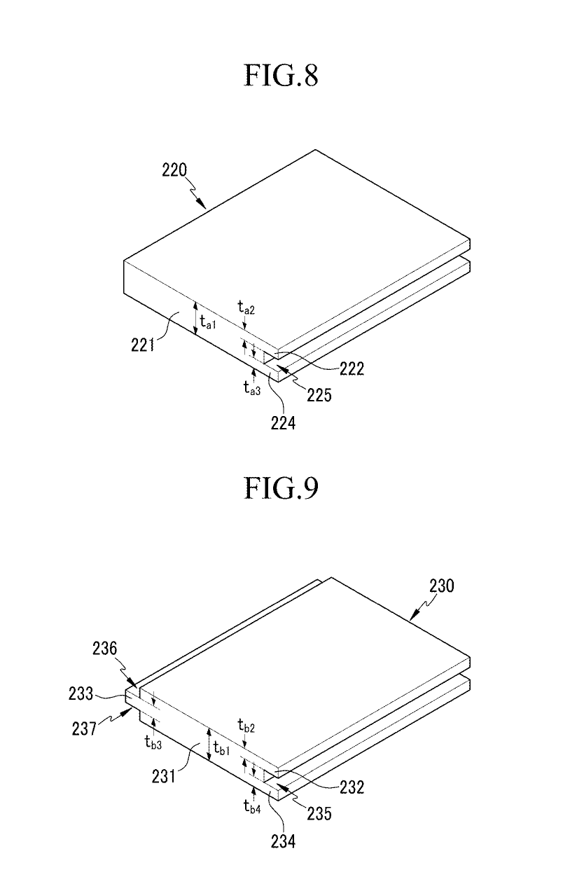

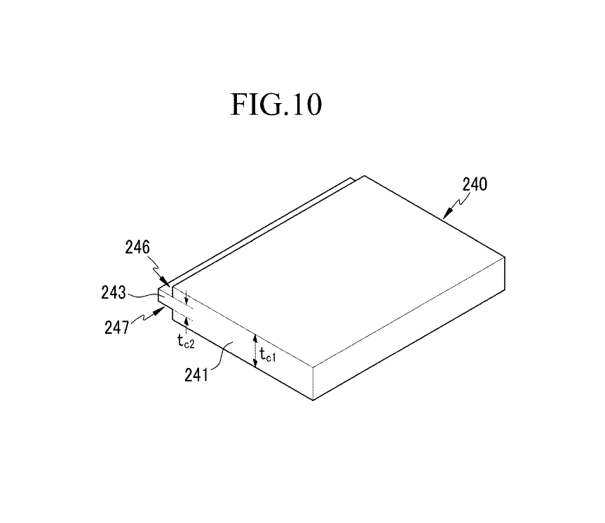

FIG. 7 is a cross-sectional view of another exemplary embodiment of a target apparatus for sputtering according to the invention. FIG. 8 is a perspective view showing another exemplary embodiment of a first target of the target apparatus for sputtering according to the invention, FIG. 9 is a perspective view showing another exemplary embodiment of a second target of the target apparatus for sputtering according to the invention, and FIG. 10 is a perspective view showing another exemplary embodiment of a third target of the target apparatus for sputtering according to the invention.

An exemplary embodiment of a target apparatus for sputtering according to the invention, as shown in FIG. 7, includes a backing plate 200, a target 250 for sputtering on the backing plate 200, and an adhesive member 210 between the target 250 for sputtering and the backing plate 200.

The target 250 for sputtering includes a first target 220, a second target 230 and a third target 240. Edges of the first to third targets 220, 230 and 240 overlap each other.

Referring to FIG. 8, the first target 220 includes a main target 221, a first protrusion 222 and a third protrusion 224 that protrude from one side surface of the main target 221, and a first space 225 positioned between the first protrusion 222 and the third protrusion 224.

The main target 221 may be plate-shaped having a flat top and/or bottom, and a predetermined thickness.

The first protrusion 222 protrudes from the upper half of the one side surface of the main target 221. The main target 221 includes four side surfaces which connect upper and lower surfaces thereof. The first protrusion 222 protrudes from the right side surface of the main target 221. The first protrusion 222 may protrude from the entire upper portion of the main target 221, when the right side surface of the main target 221 is divided into an upper portion, a middle portion and a lower portion which have the same area.

The third protrusion 224 may protrude from the entire lower portion of the one side surface of the main target 221, at a predetermined distance from the first protrusion 222 in a thickness direction of the first target 220.

The first space 225 of the first target 220 is adjacent to the right side of the main target 121 and between the first protrusion 222 and the third protrusion 224. The space positioned at the right side surface of a middle portion of the right side surface and excluding the first protrusion 222 and the third protrusion 224, is the first space 225. The first and third protrusions 222 and 224 expose a portion of the right side surface, for example, the middle portion of the right side surface of the main target 221.

Referring to FIG. 9, the second target 230 includes a main target 231, a first protrusion 232 and a third protrusion 234 that protrude from one side surface of the main target 231, and a first space 235 positioned between the first protrusion 232 and the third protrusion 234. Further, the second target 230 includes a second protrusion 233 protruding from a side surface of the main target 231 opposing the one side surface, a second space 236 positioned above the second protrusion 233, and a third space 237 positioned under the second protrusion 233.

The shape of the main target 231 of the second target 230 is similar to the shape of the main target 221 of the first target 220.

The shapes of the first protrusion 232, the third protrusion 234 and the first space 235 of the second target 230 are also similar to the shapes of the first protrusion 222, the third protrusion 224, and the first space 225 of the first target 220.

The first protrusion 232 protrudes from the upper portion of the right side surface of the main target 231. The third protrusion 234 protrudes from the lower portion of the right side surface of the main target 231. The first space 235 of the second target 230 is adjacent to the right side of the main target 231 and between the first protrusion 232 and the third protrusion 234.

The second protrusion 233 protrudes from the middle portion of the side surface of the main target 231 opposing the one side surface. The second protrusion 233 may protrude from the entire middle portion, when the left side surface of the main target 231 is divided into an upper portion, a middle portion, and a lower portion which have the same area.

The second space 236 is adjacent to the left side of the main target 231 and above the second protrusion 233. The space positioned at the left side of the upper portion of the main target 231, and excluding the second protrusion 233 on the left side surface of the main target 231, is the second space 236.

The third space 237 is adjacent to the left side surface of the main target 231 and under the second protrusion 233. The space positioned at the left side surface of the lower portion of the main target 231, and excluding the second protrusion 233 on the left side surface of the main target 231, is the third space 236.

Referring to FIG. 10, the third target 240 includes a main target 241, a second protrusion 243 that protrudes from one side surface of the main target 241, a second space 246 positioned above the second protrusion 243, and a third space 247 positioned under the second protrusion 243.

The shape of the main target 241 of the third target 240 is similar to the shape of the main target 231 of the second target 230.

The shapes of the second protrusion 243, the second space 246, and the third space 247 of the third target 240 are also similar to the shapes of the second protrusion 233, the second space 236 and the third space 247 of the second target 230.

The second protrusion 243 protrudes from the lower portion of the left side surface of the main target 241. The second space 246 is adjacent to the left side of the main target 241 and above the second protrusion 243. The third space 247 is adjacent to the left side of the main target 241 and under the second protrusion 243.

The combination relationship of the first target 220, the second target 230 and the third target 240 is described with reference to FIGS. 7 to 10.

As the right edge of the first target 220 and the left edge of the second target 230 overlap each other, the first target 220 and the second target 230 are combined. In this state, the first protrusion 222 and the third protrusion 224 of the first target 220 overlap the second protrusion 233 of the second target 230. The first protrusion 222 of the first target 220 is inserted in the second space 236 of the second target 230. The third protrusion 224 of the first target 220 is inserted in the third space 237 of the second target 230. The second protrusion 233 of the second target 230 is inserted in the first space 225 of the first target 220.

An overall thickness of the target 250 for sputtering may be substantially constant and uniform before and after the first target 220 and the second target 230 are combined. The top of the target 250 for sputtering is made flat when the first and second targets 220 and 230 are coupled.

For this configuration, the sum of the thickness tₐ₂ of the first protrusion 222 and the thickness tₐ₃ of the third protrusion 224 of the first target 220, and the thickness t_{b3} of the second protrusion 233 of the second target 230, may be substantially the same as the thickness tₐ₁ of the main target 221 of the first target 220 or the thickness t_{b1} of the main target 231 of the second target 230.

The thickness tₐ₁ of the main target 221 of the first target 220 is substantially the same as the thickness t_{b1} of the main target 231 of the second target 230.

The thickness tₐ₂ of the first protrusion 222 of the first target 220 may be substantially one-third the thickness tₐ₁ of the main target 221 of the first target 220. The thickness tₐ₃ of the third protrusion 224 of the first target 220 may be substantially one-third the thickness tₐ₁ of the main target 221 of the first target 220. The thickness t_{b3} of the second protrusion 233 of the second target 230 may be substantially one-third the thickness t_{b1} of the main target 231 of the second target 230.

The second target 230 and the third target 240 are combined by overlapping the right edge of the second target 230 and the left edge of the third target 240. In this state, the first protrusion 232 and the third protrusion 234 of the second target 230 overlap the second protrusion 243 of the third target 240. The first protrusion 232 of the second target 230 is inserted in the second space 246 of the third target 240. The third protrusion 234 of the second target 230 is inserted in the third space 247 of the third target 240. The second protrusion 243 of the third target 240 is inserted in the first space 235 of the second target 230.

An overall thickness of the target 250 for sputtering may be substantially constant and uniform before and after the second target 230 and the third target 240 are combined. The top of the target 250 for sputtering is made flat when the second and third targets 230 and 240 are coupled.

For this configuration, the sum of the thickness t_{b2} of the first protrusion 232 and the thickness t_{b4} of the third protrusion 234 of the second target 230, and the thickness t_{c2} of the second protrusion 243 of the third target 240 may be substantially the same as the thickness t_{b1} of the main target 231 of the second target 230 or the thickness t_{c1} of the main target 241 of the third target 240.

The thickness t_{b1} of the main target 231 of the second target 230 is substantially the same as the thickness t_{c1} of the main target 241 of the third target 240.

The thickness t_{b2} of the first protrusion 232 of the second target 230 may be substantially one-third the thickness t_{b1} of the main target 231 of the second target 230. The thickness t_{b4} of the third protrusion 234 of the second target 230 may be substantially one-third the thickness t_{b1} of the main target 231 of the second target 230. The thickness t_{c2} of the second protrusion 243 of the third target 240 may be substantially one-third the thickness t_{c1} of the main target 241 of the third target 240.

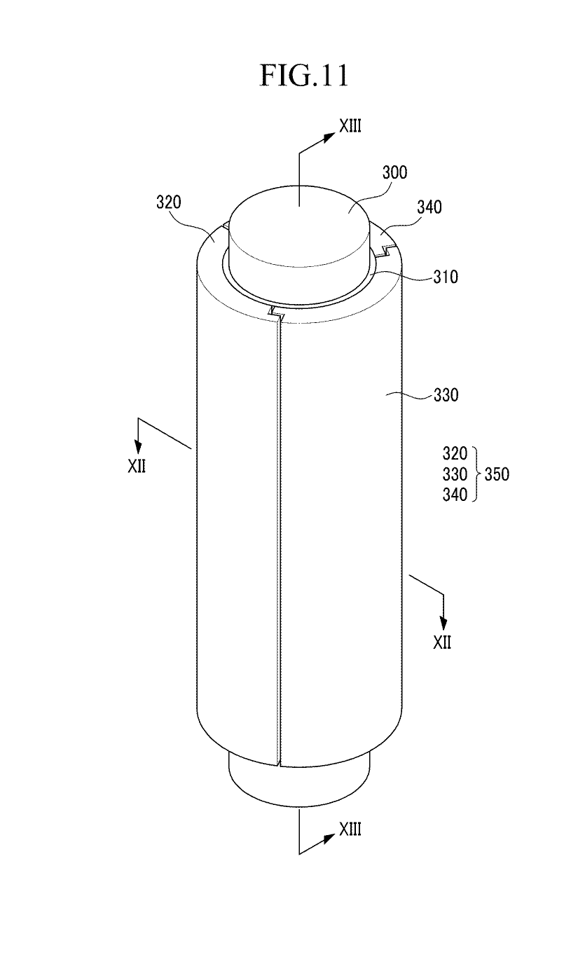

Another exemplary embodiment of a target apparatus for sputtering according to the invention is described with reference to FIGS. 11 to 13.

Since the target apparatus for sputtering according to the invention in FIGS. 11 to 13 is the substantially the same in many parts as that of the exemplary embodiment in FIGS. 1 to 5, the same parts are not described and only the parts with differences are described hereafter. The most remarkable difference from the exemplary embodiment in FIGS. 1 to 5 is the shape of a body supporting the target for sputtering, which is described in detail hereafter.

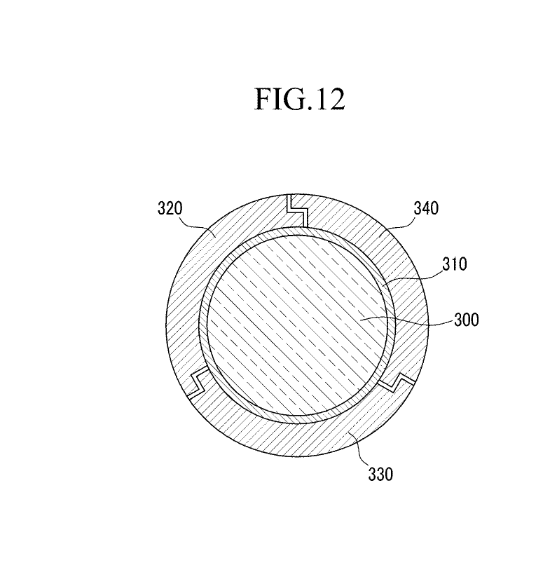

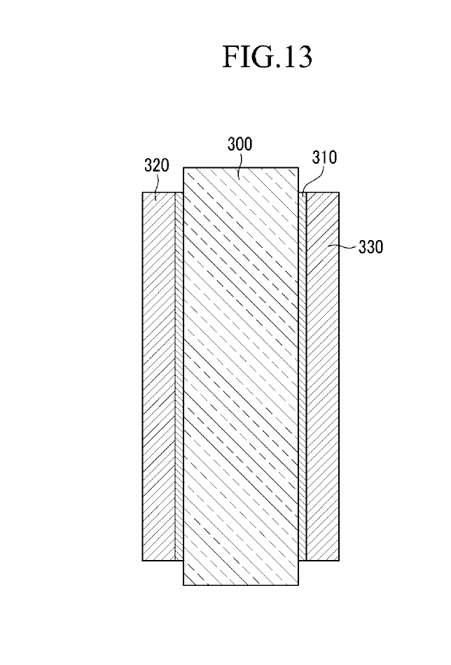

FIG. 11 is a perspective view of an exemplary embodiment of a target apparatus for sputtering according to the invention, FIG. 12 is a cross-sectional view of the target apparatus for sputtering according to the invention, taken along line XII-XII of FIG. 11, and FIG. 13 is a cross-sectional view of the target apparatus for sputtering according to the invention, taken along line XIII-XIII of FIG. 11.

An exemplary embodiment of a target apparatus for sputtering according to the invention, as shown in FIGS. 11 to 13, includes a cylindrical body 300, and a target 350 for sputtering that surrounds an outer or side surface of the body 300.

The body 300 supports the target 350 for sputtering and can rotate about a rotation axis.

An adhesive member 310 may be further provided between the target 350 for sputtering and the body 300 to fix the target 350 for sputtering to the body 300.

The target 350 for sputtering includes a first target 320, a second target 330 and a third target 340. Edges of the first to third targets 320, 330 and 340 overlap each other.

The shapes of the first to third targets 320, 330 and 340 and the combination relationship of the first to third targets 320, 330 and 340 may substantially the same as those of the exemplary embodiment of the invention shown in FIGS. 1 to 5.

However, there is a difference in that the targets are on a flat surface in the exemplary embodiment shown in FIGS. 1 to 5, whereas the first to third targets 320, 330 and 340 shown in FIGS. 11 to 13 are on a curved surface of the cylindrical body 300.

The first, second and third targets 320, 330 and 340 may be spaced apart from each other along a circumference direction of the cylindrical body 300. However, owing to the protrusions of one target inserted into a space of an adjacent target, a path from the adhesive member 310 to an outside of the targets is non-linear in a direction perpendicular to an upper surface of the adhesive 310.

In exemplary embodiments, the first to third targets 120, 130 and 140 shown in FIGS. 1 to 5 or the first to third targets 220, 230 and 240 shown in FIGS. 7 to 10 may be used as the first to third targets 320, 330 and 340 shown in FIGS. 11 to 13. The plurality of targets may be flexibly bent and attached to the body 300 to surround the body 300.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1.-4. (canceled)

5. (canceled)

6. The sputtering target apparatus of claim 18, wherein:
the first target further comprises a first space under the first protrusion, and
the second protrusion of the second target is in the first space of the first target.

7. The sputtering target apparatus of claim 6, wherein:
the second target further comprises a second space above the second protrusion, and
the first protrusion of the first target is in the second space of the second target.

8. The sputtering target apparatus of claim 18, wherein:
a third target of the plurality of targets comprises:
a third main target,
a first protrusion and
a second protrusion, and
the first protrusion and the second protrusion of the third target protrude from opposing side surfaces of the third main target.

9. The sputtering target apparatus of claim 18, wherein:
the first target further comprises a third protrusion protruding from the side surface of the first main target, and spaced apart from the first protrusion by a predetermined distance.

10. The sputtering target apparatus of claim 9, wherein:
the first, second and third protrusions overlap each other.

11. The sputtering target apparatus of claim 10, wherein:
the first protrusion of the first target protrudes from an upper thickness portion of the side surface of the first main target,
the second protrusion of the second target protrudes from a middle thickness portion of the side surface of the second main target, and
the third protrusion of the first target protrudes from a lower thickness portion of the side surface of the first main target.

12. The sputtering target apparatus of claim 11, wherein:
the first target further comprises a first space between the first protrusion and the third protrusion, and
the second protrusion of the second target is in the first space of the first target.

13. The sputtering target apparatus of claim 12, wherein:
the second target comprises:
a second space above the second protrusion, and
a third space under the second protrusion,
the first protrusion of the first target is in the second space of the second target, and
the third protrusion of the first target is in the third space of the second target.

14. The sputtering target apparatus of claim 15, wherein:
the plurality of targets includes at least one of indium zinc oxide, indium tin oxide, gallium indium zinc oxide, tin indium zinc oxide, indium zinc tin oxide and amorphous indium gallium zinc oxide.

15. A sputtering target apparatus, comprising:
a backing plate;
a sputtering target comprising a plurality of targets on the backing plate; and
an adhesive member between the backing plate and the sputtering target, wherein the adhesive member fixes the sputtering target to the backing plate,
wherein edges of the plurality of targets overlap each other.

16. The apparatus of claim 15, wherein:
the adhesive member includes indium.

17. The apparatus of claim 16, wherein:
a first target of the plurality of targets comprises:
a first main target, and
a first protrusion which protrudes from an upper thickness portion of a side surface of the first main target.

18. The apparatus of claim 17, wherein:
a second target of the plurality of targets comprises:
a second main target, and
a second protrusion which protrudes from a lower thickness portion of a side surface of the second main target.

19. The apparatus of claim 18, wherein:
the first protrusion of the first target overlaps the second protrusion of the second target.

20. A sputtering target apparatus, comprising:
a cylindrical backing body; an
a sputtering target comprising:
a plurality of targets which surround an outer side surface of the cylindrical backing body; and
an adhesive member between the cylindrical backing body and the sputtering target,
wherein the adhesive member fixes the sputtering target to the cylindrical backing body, wherein edges of the plurality of targets overlap each other.
